(19) United States
(12) Patent Application Publication
(10) Pub. No.: US 2025/0393294 A1
(43) Pub. Date: Dec. 25, 2025

(54) Semiconductor Device

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Toshifumi NISHIGUCHI, Hakusan Ishikawa (JP)

(21) Appl. No.: 18/636,162

(22) Filed: Apr. 15, 2024

(30) Foreign Application Priority Data
Sep. 14, 2023 (JP) 2023-149525

(51) Int. Cl. H10D 84/00; H10D 8/00; H10D 12/00; H10D 62/10; H10D 62/60

(52) U.S. Cl. CPC H10D 84/161; H10D 8/422; H10D 12/481; H10D 62/103; H10D 62/115; H10D 62/124; H10D 62/60

(57) ABSTRACT

A semiconductor device includes first and second electrodes, a semiconductor part, a gate electrode, and a first part that is insulative. The first and second electrodes are located in first, second, and third regions. The semiconductor part is located between the first electrode and the second electrode. The gate electrode is located in the semiconductor part in the first region. The first part is located on the first electrode in the third region. The first region is an IGBT region. The second region is a diode region. The third region separates the first region and the second region between the first region and the second region. In the third region, a bottom surface of the first part contacts the first electrode; an upper surface of the first part contacts a fourth semiconductor layer; and a side surface of the first part contacts a third semiconductor layer.

### CROSS-REFERENCE TO RELATED APPLICATIONS

This application is based upon and claims the benefit of priority from Japanese Patent Application No. 2023-149525, filed on Sep. 14, 2023; the entire contents of which are incorporated herein by reference.

### FIELD

Embodiments relate to a semiconductor device.

### BACKGROUND

IGBTs (Insulated Gate Bipolar Transistors) are widely used as semiconductor elements for power control. IGBTs (Insulated Gate Bipolar Transistors) include reverse-conducting IGBTs (RC-IGBTs) in which a diode is integrated and connected in anti-parallel.

There is a need to improve the reverse recovery characteristics of the integrated diode in such an RC-IGBT.

### BRIEF DESCRIPTION OF THE DRAWINGS

FIG. 1 is a schematic cross-sectional view illustrating a semiconductor device according to an embodiment;

FIG. 2 is a schematic cross-sectional view for describing operations of the semiconductor device according to the embodiment;

FIG. 3 is a schematic cross-sectional view for describing operations of a semiconductor device of a comparative example; and

FIG. 4 is a schematic cross-sectional view illustrating a semiconductor device according to a modification.

### DETAILED DESCRIPTION

A semiconductor device according to an embodiment includes: a first electrode located in a first region, a second region, and a third region between the first region and the second region; a second electrode located in the first, second, and third regions; a semiconductor part located between the first electrode and the second electrode; a gate electrode that extends in the semiconductor part between the second electrode and the semiconductor part in the first region and is electrically isolated from the semiconductor part; and a first part that is insulative and is located on the first electrode in the third region. The semiconductor part includes: a first semiconductor layer that is located on the first electrode in the first region, is electrically connected to the first electrode, and is of a first conductivity type; a second semiconductor layer that is located on the first electrode in the second region, is electrically connected to the first electrode, and is of a second conductivity type; a third semiconductor layer that is located on the first semiconductor layer and on the second semiconductor layer in the first and second regions and is of the second conductivity type; a fourth semiconductor layer that is located on the third semiconductor layer and on the first part in the first, second, and third regions and is of the second conductivity type; a fifth semiconductor layer that is located on the fourth semiconductor layer in the first region, is electrically connected to the second electrode, and is of the first conductivity type; a sixth semiconductor layer that is selectively provided on the fifth semiconductor layer, is electrically connected to the second electrode, and is of the second conductivity type; a seventh semiconductor layer that is located on the fourth semiconductor layer in the second and third regions, is electrically connected to the second electrode, and is of the first conductivity type; and an eighth semiconductor layer that is selectively provided on the fifth semiconductor layer, is located on the seventh semiconductor layer, is electrically connected to the second electrode, and is of the first conductivity type. The gate electrode faces the fifth semiconductor layer via a gate insulating film. A bottom surface of the first part contacts the first electrode. An upper surface of the first part contacts the fourth semiconductor layer. A side surface of the first part contacts the third semiconductor layer.

Embodiments of the invention will now be described with reference to the drawings.

The drawings are schematic or conceptual; and the relationships between the thickness and width of portions, the proportions of sizes among portions, etc., are not necessarily the same as the actual values. The dimensions and proportions may be illustrated differently among drawings, even when the same portion is illustrated.

In the specification and drawings, components similar to those already described are marked with the same reference numerals; and a detailed description is omitted as appropriate. In the following description and drawings, the notations of n⁺, n⁻, p⁺, and p⁻ indicate relative levels of the impurity concentrations. Namely, a notation marked with “+” indicates that the impurity concentration is relatively greater than that of a notation not marked with either “+” or “−”; and a notation marked with “−” indicates that the impurity concentration is relatively less than that of an unmarked notation. When both a p-type impurity and an n-type impurity are included in each region, these notations indicate relative levels of the net impurity concentrations after the impurities compensate each other.

According to the embodiments described below, each embodiment may be implemented by inverting the p-type and the n-type of the semiconductor regions.

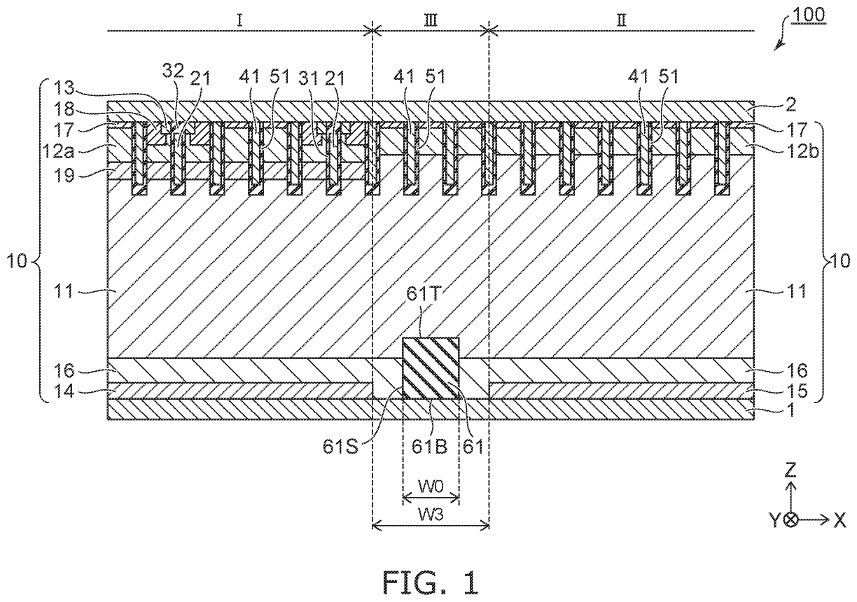

FIG. 1 is a schematic cross-sectional view illustrating the semiconductor device according to the embodiment.

As shown in FIG. 1, the semiconductor device 100 according to the embodiment includes a collector electrode 1, an emitter electrode 2, a semiconductor part 10, a gate electrode 21, and an insulating body 61. The semiconductor part 10 is located between the collector electrode 1 and the emitter electrode 2. The insulating body 61 is located on the collector electrode 1 and extends into the semiconductor part 10 from the collector electrode 1.

The collector electrode (a first electrode) 1 is located at the back surface of the semiconductor part 10 and functions as one major electrode of the RC-IGBT. The emitter electrode (a second electrode) 2 is located at the front side of the semiconductor part 10 and functions as another major electrode of the RC-IGBT. The gate electrode 21 faces the semiconductor part 10 via a gate insulating film 31.

The semiconductor device 100 includes a first region I, a second region II, and a third region III. The third region III is located between the first region I and the second region II.

In the first region I, the semiconductor device 100 operates mainly as an IGBT. For an n-type IGBT, an operation as an IGBT refers to an operation in which the IGBT is switched on when a voltage that is sufficiently greater than a gate threshold voltage is applied to the gate electrode 21; and the IGBT is switched off when a voltage that is sufficiently less than the gate threshold voltage is applied to the gate electrode 21.

In the second region II, the semiconductor device 100 operates mainly as a diode. For an n-type IGBT, an operation as a diode refers to an operation in which a current flows through the emitter electrode 2 and the current flows out from the collector electrode 1 when the IGBT is off. Hereinbelow, the semiconductor device 100 operating as an IGBT may be called an IGBT operation; and the semiconductor device 100 operating as a diode may be called a diode operation.

The third region III electrically isolates the first region I and the second region II. A distance W3 is the width of the third region III, and is the distance between the first region I and the second region II.

The collector electrode 1, the semiconductor part 10, and the emitter electrode 2 are located in the first, second, and third regions I, II, and III.

Hereinbelow, the configuration of the semiconductor device 100 may be described using an XYZ coordinate system. The direction from the collector electrode 1 toward the emitter electrode 2 is described as a direction of a Z-axis. The first region I, the third region III, and the second region II are arranged in this order in a direction of an X-axis orthogonal to the Z-axis. For example, the first region I and the second region II are alternately arranged with the third region III interposed. That is, in the specific example of FIG. 1, the first region I may be located at the positive-direction side of the X-axis of the second region II with the third region III interposed. Also, the second region II may be located at the negative-direction side of the X-axis of the first region I with the third region III interposed. The repetition of the arrangement of the first to third regions I to III is applicable in a Y-axis direction. 5

The interference between the operation in the first region I and the operation in the second region II can be reduced as the distance W3 is increased. On the other hand, as the distance W3 is increased, the area of the semiconductor device 100 when viewed in plan increases, and the cost performance decreases.

In the semiconductor device 100 according to the embodiment, the insulating body (a first part) 61 is located in the third region III. A width W0 of the insulating body 61 is equal to the distance W3 or less than the distance W3. By including the insulating body 61 in the semiconductor device 100, the interference between the operation in the first region I and the operation in the second region II can be suppressed even when the distance W3 is short.

The interference between the operation in the first region I and the operation in the second region II refers to the movement, into the second region II, of the minority carriers injected into the first region I in the diode operation of the semiconductor device 100. When the minority carriers injected into the first region I move into the second region II, the charge amount of the minority carriers in the second region II becomes excessive, and the reverse recovery time increases. The insulating body 61 is located in the third region III to limit the movement of the minority carriers from the first region I to the second region II.

The configuration of the semiconductor device 100 will now be described in more detail. The semiconductor device 100 is an n-type RC-IGBT in the following description. In the diode operation of the semiconductor device 100, the collector electrode 1 functions as a cathode electrode of the diode; and the emitter electrode 2 functions as an anode electrode of the diode.

The semiconductor part 10 includes an n⁻-type drift layer 11, a p⁻-type base layer 12a, a p-type anode layer 12b, an n⁺-type source layer 13, a p⁺-type collector layer 14, an n⁺-type cathode layer 15, an n⁺-type buffer layer 16, and a p⁺-type emitter layer 17. The semiconductor part 10 further includes a p⁺-type contact layer 18 and an n-type barrier layer 19. The semiconductor part 10 includes, for example, Si.

The p⁺-type collector layer (a first semiconductor layer) 14 is located on the collector electrode 1 in the first region I and is electrically connected to the collector electrode 1. The p⁺-type collector layer 14 is not located in the second and third regions II and III.

The n⁺-type cathode layer (a second semiconductor layer) 15 is located on the collector electrode 1 in the second region II and is electrically connected to the collector electrode 1. The n⁺-type cathode layer 15 is not located in the first and third regions I and III.

The n⁺-type buffer layer (a third semiconductor layer) 16 is located on the p⁺-type collector layer 14 in the first region I. The n⁺-type buffer layer 16 is located on the n⁺-type cathode layer 15 in the second region II. The n⁺-type buffer layer 16 is located on the collector electrode 1 in the third region III. In the specific example of FIG. 1, the n⁺-type buffer layer 16 surrounds the perimeter of the insulating body 61 in the third region III.

The n⁻-type drift layer (a fourth semiconductor layer) 11 is located on the n⁺-type buffer layer 16 in the first and second regions I and II. The n⁻-type drift layer 11 is located on the insulating body 61 in the third region III. In the specific example of FIG. 1, the n⁻-type drift layer 11 is located on the n⁺-type buffer layer 16 in the third region III.

The n-type barrier layer 19 is located on the n⁻-type drift layer 11 in the first region I. The n-type barrier layer 19 is not located in the second and third regions II and III.

The p⁻-type base layer (a fifth semiconductor layer) 12a is located on the n-type barrier layer 19 in the first region I. The p⁻-type base layer 12a is not located in the second and third regions II and III.

The p-type anode layer (a seventh semiconductor layer) 12b is located on the n⁻-type drift layer 11 in the second and third regions II and III. The p-type anode layer 12b is not located in the first region I.

The n⁺-type source layer (a sixth semiconductor layer) 13 is selectively provided on the p⁻-type base layer 12a in the first region I. The n⁺-type source layer 13 is not located in the second and third regions II and III.

The p⁺-type emitter layer (an eighth semiconductor layer) 17 is selectively provided on the p⁻-type base layer 12a in the first region I. The p⁺-type emitter layer 17 is located on the p-type anode layer 12b in the second and third regions II and III.

The p⁺-type contact layer 18 is selectively provided on the p⁻-type base layer 12a in the first region I. In the first region I, the p⁺-type contact layer 18 is located at a position at which the p⁺-type emitter layer 17 is not located. The p⁺-type contact layer 18 is not located in the second and third regions II and III.

The impurity concentration of the n⁻-type drift layer 11 is less than the impurity concentrations of the n⁺-type cathode layer 15, the n⁺-type buffer layer 16, and the n⁺-type source layer. Also, the impurity concentration of the n⁻-type drift layer 11 is less than the impurity concentration of the n-type barrier layer 19. Therefore, when a reverse bias is applied between the n⁻-type drift layer 11 and the p⁻-type base layer 12a, a depletion layer spreads in the n⁻-type drift layer 11; and the desired breakdown voltage is realized. Also, when a reverse bias is applied between the n⁻-type drift layer 11 and the p-type anode layer 12b, a depletion layer spreads in the n⁻-type drift layer 11; and a desired breakdown voltage is realized.

The impurity concentration of the p⁺-type emitter layer 17 is greater than the impurity concentration of the p⁻-type base layer 12a. Also, the impurity concentration of the p⁺-type emitter layer 17 is greater than the impurity concentration of the p-type anode layer 12b.

The insulating body 61 is located in the third region III, and is favorably provided in the entire third region III. The insulating body 61 is located on the collector electrode 1 and contacts the collector electrode 1 at a lower surface 61B. The insulating body 61 contacts the n⁺-type buffer layer 16 at a side surface 61S. The insulating body 61 divides the n⁺-type buffer layer 16. Favorably, the insulating body 61 extends in the n⁻-type drift layer 11 as in the specific example of FIG. 1. The insulating body 61 contacts the n⁻-type drift layer 11 at an upper surface 61T, and contacts the n⁻-type drift layer 11 at the side surface 61S of the upper portion of the insulating body 61.

The insulating body 61 includes an insulating material such as Si oxide, Si nitride, etc., e.g., SiO₂. As long as the insulating body 61 can block movement of the holes, the insulating body 61 may be another insulator, and may include, for example, an insulating material such as rubber, other resins, etc. The interior of the insulating body 61 may not be completely filled with an insulator and may include a void, etc.

For example, the insulating body 61 can be formed as follows. Namely, in the third region III, a recess that extends through the n⁺-type buffer layer 16 from the back surface of the semiconductor part 10 and reaches the n⁻-type drift layer 11 is formed, and a SiO₂ film is formed in the recess. The recess is made of a bottom surface that faces the upper surface 61T of the insulating body 61, and a side surface that is continuous with the bottom surface and faces the side surface 61S of the insulating body 61. For example, anisotropic etching such as reactive ion etching (RIE) or the like can be used to form the recess. For example, chemical vapor deposition (CVD) can be used to form the SiO₂ film.

In the first region I, the gate electrode 21 extends from the surface of the semiconductor part 10 into the interior, and is electrically isolated from the semiconductor part 10. The gate electrode 21 faces the p⁻-type base layer 12a via the gate insulating film 31. The gate electrode 21 faces the n-type barrier layer 19 via the gate insulating film 31. The gate electrode 21 faces a portion of the n⁻-type drift layer 11 via the gate insulating film 31.

A conductive body 41 is selectively provided in the first region I. In the specific example of FIG. 1, the conductive body 41 is located between two gate electrodes 21 arranged in the X-axis direction. The conductive body 41 extends from the surface of the semiconductor part 10 into the interior and is electrically isolated from the semiconductor part 10.

The conductive body 41 faces the p⁻-type base layer 12a via an insulating film 51 in the first region I. In the first region I, the conductive body 41 faces the p⁺-type emitter layer 17, which is selectively provided, via the insulating film 51. In the first region I, the conductive body 41 faces the p⁺-type contact layer 18, which is selectively provided, via the insulating film 51. The conductive body 41 faces the n-type barrier layer 19 in the first region I; and the conductive body 41 faces a portion of the n⁻-type drift layer 11 in the first region I.

In each of the second and third regions II and III, the conductive body 41 extends from the surface of the semiconductor part 10 into the interior, and is electrically isolated from the semiconductor part 10.

In each of the second and third regions II and III, the conductive body 41 faces the p-type anode layer 12b via the insulating film 51. In each of the second and third regions II and III, the conductive body 41 faces the p⁺-type emitter layer 17 via the insulating film 51. In each of the second and third regions II and III, the conductive body 41 faces a portion of the n⁻-type drift layer 11 via the insulating film 51.

Although not illustrated, the gate electrode 21 and the conductive body 41 extend in the Y-axis direction and are arranged in stripe shapes when viewed in plan. The gate electrode 21 and the conductive body 41 include, for example, polycrystalline Si.

The emitter electrode 2 is located on the n⁺-type source layer 13, on the p⁺-type emitter layer 17, on the p⁺-type contact layer 18, and on the conductive body 41 in the first region I. The emitter electrode 2 is electrically connected to the n⁺-type source layer 13, the p⁺-type emitter layer 17, the p⁺-type contact layer 18, and the conductive body 41 in the first region I.

The emitter electrode 2 is located on the gate electrode 21 in the first region I. The emitter electrode 2 is electrically isolated from the gate electrode 21 by an inter-layer insulating film 32 located between the emitter electrode 2 and the gate electrode 21.

In each of the second and third regions II and III, the emitter electrode 2 is located on the p⁺-type emitter layer 17 and on the conductive body 41. In each of the second and third regions II and III, the emitter electrode 2 is electrically connected to the p⁺-type emitter layer 17 and the conductive body 41.

Operations of the semiconductor device 100 according to the embodiment will now be described.

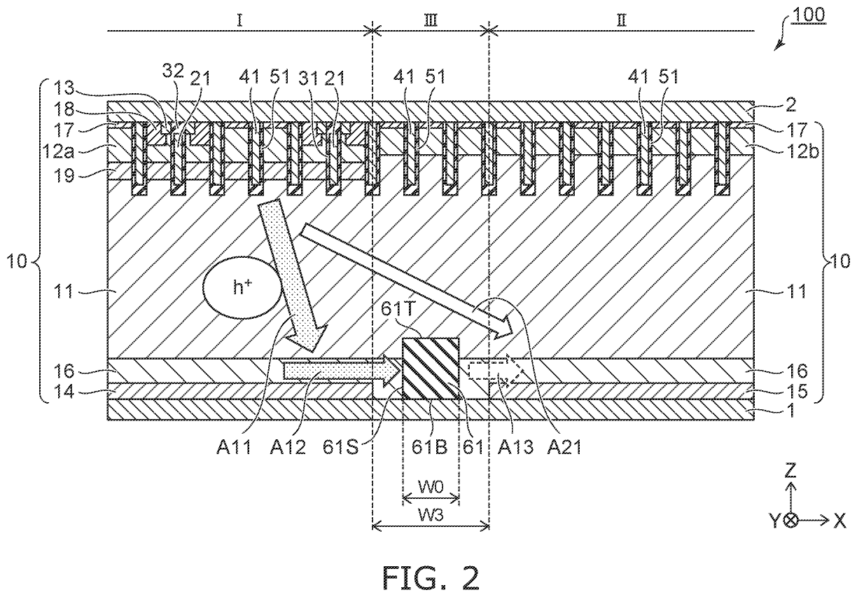

FIG. 2 is a schematic cross-sectional view for describing operations of the semiconductor device according to the embodiment.

In FIG. 2, the paths and directions of the movements of the holes in the diode operation of the semiconductor device 100 are illustrated by arrows A11 to A21.

First, the IGBT operation of the semiconductor device 100 will be described.

When the semiconductor device 100 is turned on in the IGBT operation, a voltage with respect to the emitter electrode 2 that is sufficiently greater than a gate threshold is applied to the gate electrode 21. An inversion layer is formed by the voltage at the surface of the p⁻-type base layer 12a. Electrons that are supplied from the n⁺-type source layer 13 flow into the inversion layer, the n⁻-type drift layer 11, and the n⁺-type buffer layer 16.

Because a voltage that is higher than that of the emitter electrode 2 is applied to the collector electrode 1, the p⁺-type collector layer 14 injects holes into the n⁺-type buffer layer 16 and the n⁻-type drift layer 11. The IGBT is turned on thereby.

When the semiconductor device 100 is turned off in the IGBT operation, a voltage with respect to the emitter electrode 2 that is sufficiently less than the gate threshold is applied to the gate electrode 21. For example, by applying a negative voltage with respect to the voltage of the emitter electrode 2, an accumulation layer is formed in the p⁻-type base layer 12a.

The holes in the n⁻-type drift layer 11 are recovered at the emitter electrode 2 side via the accumulation layer and the p⁻-type base layer 12a where the accumulation layer is not formed. When the accumulation layer is formed in the p⁻-type base layer 12a by applying a sufficiently low voltage to the emitter electrode 2, excess holes are recovered; and the turn-off speed of the semiconductor device 100 is increased.

The diode operation of the semiconductor device 100 will now be described.

In the diode operation as shown in FIG. 2, a voltage that is higher than that of the collector electrode 1 is applied to the emitter electrode 2, and so holes are injected into the n⁻-type drift layer 11 from the p⁺-type emitter layer 17 in each of the second and third regions II and III. Electrons that correspond to the charge amount of the injected holes are supplied from the n⁺-type cathode layer 15; and a current flows from the emitter electrode 2 toward the collector electrode 1.

In the first region I as well, holes are injected from the p⁺-type emitter layer 17 and the p⁺-type contact layer 18 into the n⁻-type drift layer 11 via the n-type barrier layer 19.

The paths of the holes injected into the n⁻-type drift layer 11 in the first region I to the n⁻-type drift layer 11 in the second region II are a first path illustrated by arrows A11, A12, and A13, and a second path illustrated by arrow A21.

Arrows A11, A12, and A13 each are portions of the first path. In other words, arrow A11 illustrates a portion of the path from the n⁻-type drift layer 11 to the n⁺-type buffer layer 16 in the first region I. Arrow A12 illustrates a portion of the path from the n⁺-type buffer layer 16 in the first region I to the n⁺-type buffer layer 16 in the third region III. Arrow A13 illustrates a portion of the path from the n⁺-type buffer layer 16 in the third region III to the n⁺-type buffer layer 16 in the second region II.

In the second path, arrow A21 illustrates the path from the n⁻-type drift layer 11 in the first region I, through the n⁻-type drift layer 11 in the third region III, to the n⁻-type drift layer 11 in the second region II.

In the semiconductor device 100 according to the embodiment, the insulating body 61 is located on the collector electrode 1 in the third region III. The insulating body 61 extends through the n⁺-type buffer layer 16 in the third region III and electrically isolates the n⁺-type buffer layer 16 between the first region I and the second region II. Therefore, in the first path as illustrated by the broken line of arrow A13, the movement into the second region II of the holes injected into the n⁻-type drift layer 11 in the first region I is blocked by the insulating body 61 in the third region III.

A portion of the first path includes the n⁺-type buffer layer 16 that has a lower sheet resistance than the n⁻-type drift layer 11. As a result, the resistance value of the first path made of arrows A11, A12, and A13 of FIG. 2 is less than the resistance value of the second path made of arrow A21. Therefore, substantially all of the holes injected into the n⁻-type drift layer 11 in the first region I would move to the second region II via the first path, but are blocked by the insulating body 61 and therefore cannot reach the second region II; therefore, degradation of the reverse recovery characteristics in the second region II can be suppressed.

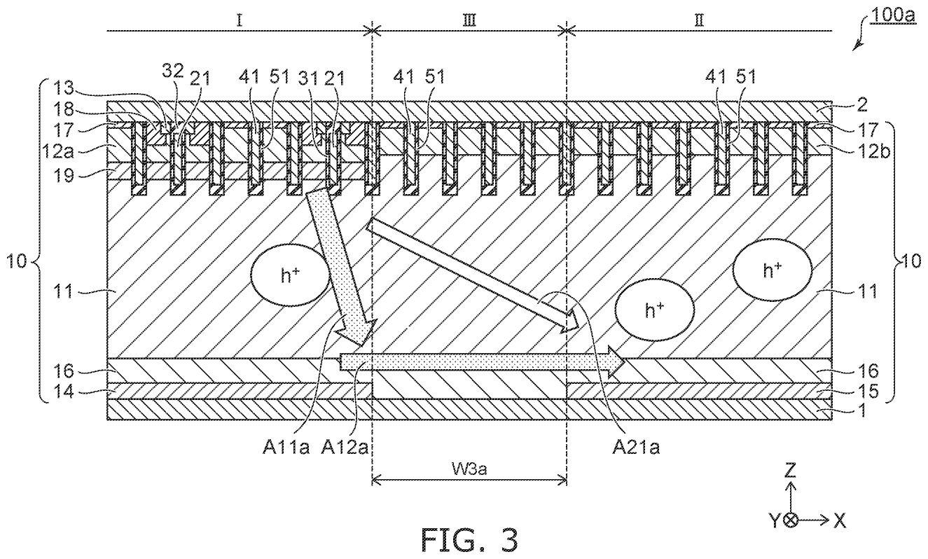

FIG. 3 is a schematic cross-sectional view for describing operations of a semiconductor device 100a of a comparative example.

In the semiconductor device 100a of the comparative example as shown in FIG. 3, instead of the insulating body 61 located in the third region III, a distance W3a of the third region III is set to be sufficiently long.

Arrows A11a and A12a each are portions of the first path. Arrow A21a is included in the second path. The lengths of the paths each are set to be sufficiently long, so that the resistance values of the paths can be substantially large. The movement into the second region II of the holes injected into the n⁻-type drift layer 11 in the first region I can be suppressed thereby.

On the other hand, the distance W3a of the third region III is long, and the area of the region that does not contribute to the IGBT operation and the diode operation increases. Therefore, the cost performance of the semiconductor device 100a is reduced.

### Modification

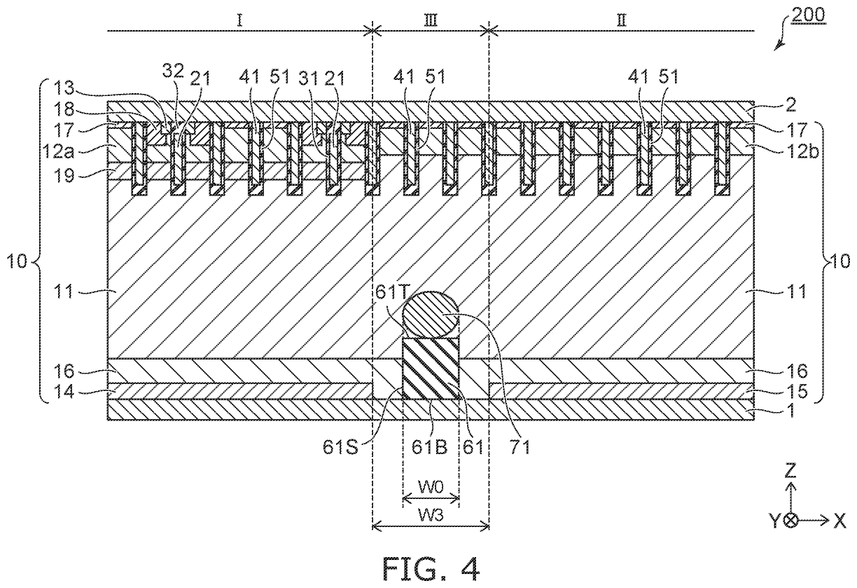

FIG. 4 is a schematic cross-sectional view illustrating a semiconductor device according to a modification.

As shown in FIG. 4, the semiconductor device 200 according to the modification includes a high-resistance part (a second part) 71 in the third region III. The high-resistance part 71 is located in the n⁻-type drift layer 11 in the third region III. The high-resistance part 71 is located on the upper surface 61T of the insulating body 61. The n-type impurity concentration of the high-resistance part 71 is less than the n-type impurity concentration of the n⁻-type drift layer 11.

In the third region III, the high-resistance part 71 has a lower sheet resistance than the n⁻-type drift layer 11. Therefore, the movement of the holes of the first path shown in FIG. 2 can be more reliably blocked; the movement of the holes in the second path can be suppressed; and degradation of the reverse recovery characteristics in the second region II can be more reliably prevented.

For example, the high-resistance part 71 can be formed as follows. Namely, the high-resistance part 71 can be formed by forming the recess for forming the insulating body 61, and then introducing a p-type impurity to the n⁻-type drift layer 11 via the bottom surface of the recess. For example, ion implantation can be used to introduce the p-type impurity.

Effects of the semiconductor device 100 according to the embodiment and the semiconductor device 200 according to the modification will now be described.

The n⁺-type buffer layer 16 is included in the semiconductor devices 100 and 200 to prevent the depletion layer formed in the n⁻-type drift layer 11 from extending to the collector electrode 1 when a reverse bias is applied between the collector electrode 1 and the emitter electrode 2. On the other hand, in the diode operations of the semiconductor devices 100 and 200, the n⁺-type buffer layer 16 may become a path for movement into the second region II of the holes injected into the first region I. The semiconductor devices 100 and 200 according to the embodiment include the insulating body 61 to divide the n⁺-type buffer layer 16 in the third region III between the first region I and the second region II. Therefore, the movement of the holes into the second region II via the n⁺-type buffer layer 16 is blocked, the charge amount of excess holes in the second region II is reduced, and the reverse recovery characteristics are improved.

By sufficiently increasing the width W0 of the insulating body 61, the movement of the holes from the first region I to the second region II can be more reliably blocked. The movement of the holes from the first region I to the second region II can be blocked more reliably by the insulating body 61 sufficiently extending from the n⁺-type buffer layer 16 into the interior of the n⁻-type drift layer 11.

In the semiconductor device 200 according to the modification, the high-resistance part 71 is included on the insulating body 61; therefore, the movement of the holes from the first region I to the second region II can be even more reliably blocked.

In the embodiments above, the relative levels of the impurity concentrations between the semiconductor regions can be confirmed using, for example, a SCM (scanning capacitance microscope). The carrier concentration in each semiconductor region can be considered to be equal to the activated impurity concentration in each semiconductor region. Accordingly, the relative levels of the carrier concentrations between the semiconductor regions also can be confirmed using SCM. The impurity concentration in each semiconductor region can be measured by, for example, SIMS (secondary ion mass spectrometry).

While certain embodiments of the inventions have been illustrated, these embodiments have been presented by way of example only, and are not intended to limit the scope of the inventions. These novel embodiments may be embodied in a variety of other forms; and various omissions, substitutions, modifications, etc., can be made without departing from the spirit of the inventions. These embodiments and their modifications are within the scope and spirit of the inventions, and are within the scope of the inventions described in the claims and their equivalents. The embodiments described above can be implemented in combination with each other.

What is claimed is:

1. A semiconductor device, comprising:
a first electrode located in a first region, a second region, and a third region between the first region and the second region;
a second electrode located in the first, second, and third regions;
a semiconductor part located between the first electrode and the second electrode;
a gate electrode extending in the semiconductor part between the second electrode and the semiconductor part in the first region, the gate electrode being electrically isolated from the semiconductor part; and
a first part located on the first electrode in the third region, the first part being insulative,
the semiconductor part including
a first semiconductor layer located on the first electrode in the first region, the first semiconductor layer being electrically connected to the first electrode, the first semiconductor layer being of a first conductivity type,
a second semiconductor layer located on the first electrode in the second region, the second semiconductor layer being electrically connected to the first electrode, the second semiconductor layer being of a second conductivity type,
a third semiconductor layer located on the first semiconductor layer and on the second semiconductor layer in the first and second regions, the third semiconductor layer being of the second conductivity type,
a fourth semiconductor layer located on the third semiconductor layer and on the first part in the first, second, and third regions, the fourth semiconductor layer being of the second conductivity type,
a fifth semiconductor layer located on the fourth semiconductor layer in the first region, the fifth semiconductor layer being electrically connected to the second electrode, the fifth semiconductor layer being of the first conductivity type,
a sixth semiconductor layer selectively provided on the fifth semiconductor layer, the sixth semiconductor layer being electrically connected to the second electrode, the sixth semiconductor layer being of the second conductivity type,
a seventh semiconductor layer located on the fourth semiconductor layer in the second and third regions, the seventh semiconductor layer being electrically connected to the second electrode, the seventh semiconductor layer being of the first conductivity type, and
an eighth semiconductor layer located on the seventh semiconductor layer and selectively provided on the fifth semiconductor layer, the eighth semiconductor layer being electrically connected to the second electrode, the eighth semiconductor layer being of the first conductivity type,
the gate electrode facing the fifth semiconductor layer via a gate insulating film,
a bottom surface of the first part contacting the first electrode,
an upper surface of the first part contacting the fourth semiconductor layer,
a side surface of the first part contacting the third semiconductor layer.

2. The device according to claim 1, wherein
the side surface of the first part contacts the fourth semiconductor layer at an upper portion of the first part.

3. The device according to claim 1, further comprising:
a second part on the first part in the third region,
the second part having a lower carrier concentration than the fourth semiconductor layer.

4. The device according to claim 3, wherein
the second part contacts the upper surface of the first part.

5. The device according to claim 1, wherein
the third semiconductor layer is located on the first electrode, and
the side surface of the first part contacts the third semiconductor layer.

6. The device according to claim 1, wherein
the first part divides the third semiconductor layer in the first region and the third semiconductor layer in the second region.

7. The device according to claim 1, wherein
the first part includes Si oxide or Si nitride.

8. The device according to claim 1, wherein
the first part includes a void inside the first part.
